(19) United States
(12) Patent Application Publication
(10) Pub. No.: US 2023/0335628 A1
(43) Pub. Date: Oct. 19, 2023

(54) INSULATED GATE BIPOLAR TRANSISTOR AND METHOD OF MANUFACTURING SAME

(71) Applicant: DB HiTek Co., Ltd., Bucheon-si (KR)

(72) Inventor: Ji Sun KIM, Yongin-si (KR)

(21) Appl. No.: 18/161,232

(22) Filed: Jan. 30, 2023

(30) Foreign Application Priority Data
Apr. 18, 2022 (KR) 10-2022-0047300

(51) Int. Cl. H01L 29/739; H01L 29/417; H01L 29/10; H01L 29/423; H01L 29/66; H01L 29/40

(52) U.S. Cl. CPC H01L 29/7398; H01L 29/41708; H01L 29/1095; H01L 29/4236; H01L 29/7397; H01L 29/66333; H01L 29/404

(57) ABSTRACT

The present disclosure relates to an insulated gate bipolar transistor and a method of manufacturing the same. More particularly, the present disclosure relates to an insulated gate bipolar transistor and a manufacturing method that improves breakdown voltage characteristics and includes a second ring region having a first conductivity type in contact with a first ring region having the first conductivity type in the termination region.

The present application claims priority to Korean Patent Application No. 10-2022-0047300, filed Apr. 18, 2022, the entire contents of which are incorporated herein for all purposes by this reference.

### BACKGROUND OF THE INVENTION

### 1. Field of the Invention

The present disclosure relates to an insulated gate bipolar transistor (IGBT) and a method of manufacturing the same. More particularly, the present disclosure relates to an insulated gate bipolar transistor (IGBT) including a termination region, a second ring region having a first conductivity type, in contact with a first ring region having the first conductivity type to improve breakdown voltage characteristics of the IGBT, and a method of manufacturing the same.

### 2. Description of the Related Art

An insulated gate bipolar transistor (IGBT) is an ideal device combining the advantages of a MOSFET and a bipolar transistor: an insulated gate structure and a high current density. Specifically, the IGBT has the advantage of bipolar operation, which can significantly reduce on-resistance by generating conductivity modulation.

As a power semiconductor device, an insulated gate bipolar transistor typically must withstand voltages up to a predetermined breakdown voltage when the gate is turned off, and reliable operation at high temperatures is an important factor of the IGBT.

Therefore, the present disclosure intends to provide a novel insulated gate bipolar transistor with an improved structure capable of ensuring high-temperature reliability and a high breakdown voltage, and a method of manufacturing the same. The details will be described below.

### LITERATURE OF THE RELATED ART

Korean Patent Application Publication No. 10-2009-0070516, entitled “Insulated Gate Bipolar Transistor and Manufacturing Method Thereof.”

### SUMMARY OF THE INVENTION

The present disclosure has been made to solve the problems occurring in the related art, an objective of the present disclosure is to provide an insulated gate bipolar transistor including a first ring region (e.g., a heavily doped first conductivity type region) in a drift region of the transistor and within a termination region, to enable the transistor to withstand a relatively high voltage, and to provide a manufacturing method thereof.

In addition, another objective of the present disclosure is to provide an insulated gate bipolar transistor including a second ring region (e.g., a lightly doped first conductivity type region) in contact with the first ring region (or a first side thereof) to deter reaching a critical electric field at a certain time, and to provide a manufacturing method thereof.

In addition, a further objective of the present disclosure is to provide an insulated gate bipolar transistor having improved high temperature reverse bias (HTRB) characteristics by including the second ring, which can move a breakdown point to a position or location under the second ring region, and to provide a manufacturing method thereof.

To achieve the above-mentioned objectives, the present disclosure proposes various embodiments described below.

In a first aspect, one or more embodiments relates to an insulated gate bipolar transistor including a collector electrode; a collector layer on the collector electrode; a drift region on or over the collector layer; a field oxide on a surface of the drift region in a termination region (e.g., of the insulated gate bipolar transistor); a first ring region in the drift region (e.g., in the termination region); a second ring region in contact with the first ring region in the drift region; and a field plate on the field oxide and connected to the first ring region.

In another embodiment, the first ring region may comprise a heavily doped first conductivity type region, and the second ring region may comprise a lightly doped first conductivity type region.

In a further embodiment, the first ring region and the second ring region may be at a surface of the drift region or adjacent to the drift region, and the second ring region has a depth that is about half of a depth of the first ring region.

In a yet further embodiment, the second ring region may be in contact with a first side of the first ring region, and the first side of the first ring region may be relatively far or distant from a neighboring or adjacent active region (e.g., of an adjacent IGBT).

In a yet further embodiment of the present disclosure, the second ring region may be in contact with first and second sides of the first ring region, the first side being relatively far or distant from the neighboring or adjacent active region, the second side being relatively close or nearer to the neighboring or adjacent active region (e.g., closer to the neighboring or adjacent active region than the first side).

In a yet further embodiment, the field plate may be connected to the first ring region via a contact hole in the field oxide.

In a second aspect, one or more embodiments relate to an insulated gate bipolar transistor including a collector electrode; a collector layer having a first conductivity type on the collector electrode; a drift region having a second conductivity type on or over the collector layer; a body region having the first conductivity type in the drift region (and, for example, in an active region of the insulated gate bipolar transistor); a plurality of trench gates in (e.g., extending to a lower end of) the body region (e.g., in the active region); an interlayer insulating film on or over the trench gates; an emitter region having the second conductivity type on the body region; an emitter electrode on the interlayer insulating film; a field oxide on the drift region (e.g., in a termination region of the IGBT); a first ring region comprising a heavily doped first conductivity type region in the drift region (e.g., in the termination region; a second ring region comprising a lightly doped first conductivity type region in the drift region, the second ring region being in contact with the first ring region (e.g., in the drift region); and a field plate through and/or on the field oxide, connected to the first ring region.

In another embodiment, the insulated gate bipolar transistor further includes a body contact having the first conductivity type, in contact with the emitter region in the body region.

In a further embodiment, the insulated gate bipolar transistor further includes a buffer layer having the second conductivity type, on the collector layer.

In a yet further embodiment, each of the trench gates includes a trench, a gate insulating film on an inner wall surface of the trench, and a gate electrode on the gate insulating film (e.g., filling the trench).

In a yet further embodiment, a plurality of the first ring regions may be spaced from each other in the drift region and may be connected to respective ones of a plurality of the field plates (e.g., at one side thereof), and a plurality of the second ring regions may be spaced from each other and in contact with respective ones of the first ring regions in the drift region.

In a yet further embodiment, each of the second ring regions is electrically connected to at least one side of an adjacent or corresponding one of the first ring regions.

In a yet further embodiment, each of the second ring regions may have a height or depth smaller than that of an adjacent one of the first ring regions.

In a third aspect, one or more embodiments relates to a method of manufacturing an insulated gate bipolar transistor including forming a collector layer on a substrate; forming a drift region on or over the collector layer; forming a body region on or in the drift region (e.g., in an active region of the insulated gate bipolar transistor); forming a plurality of trench gates (e.g., extending from the body region to the drift region); forming an emitter region on or in the body region (e.g., between adjacent ones of the trench gates), spaced from each other; forming an interlayer insulating film on or over the trench gates; forming a plurality of first ring regions on or in the drift region (e.g., in a termination region of the insulated gate bipolar transistor); and forming a plurality of second ring regions on or in the drift region such that the second ring regions are in contact with respective ones of the first ring regions.

In another embodiment, forming the first ring region and forming the second ring region includes forming a plurality of first implantation layers, each of which comprises a heavily doped first conductivity type region, on or in the drift region (and, e.g., in the termination region); forming a plurality of second implantation layers, each of which comprises a lightly doped first conductivity type region, such that the second implantation layers are in contact with the respective or corresponding ones of the first implantation regions; and diffusing the first implant layer and the second implant layer (e.g., by thermal diffusion and/or activation).

In a further embodiment, the method further includes forming a field oxide on the drift region (e.g., in the termination region); and forming a plurality of field plates electrically connected to corresponding ones of the first ring regions, through and/or on the field oxide.

In a yet further embodiment, the method further includes forming an emitter electrode (e.g., in the active region) on the interlayer insulating film and the body region. The emitter electrode and the field plate may be formed substantially simultaneously.

In a yet further embodiment, each of the second ring regions may be connected to at least one side of a corresponding one of the first ring regions.

With the configurations described above, the present disclosure has various advantages described below.

The first ring region, which comprises a heavily doped first conductivity type region in the drift region, may be in the termination region of the insulated gate bipolar transistor, and may increase the breakdown voltage of the transistor.

In addition, the second ring region, which comprises a lightly doped first conductivity type region, may contact at least one side of the first ring region, to deter or delay reaching the critical electric field at or to a certain time, thereby improving the breakdown voltage characteristics of the transistor.

In addition, as described above, due to the formation of the second ring region, a breakdown point (e.g., of the insulated gate bipolar transistor) may move to a position or location under the second ring region, thereby improving the HTRB characteristics of the transistor.

On the other hand, even if some effects are not explicitly mentioned herein, when the not-mentioned effects are expected from the technical features of the present disclosure, such effects and potential effects may be treated as if described in the present specification.

### BRIEF DESCRIPTION OF THE DRAWINGS

FIG. 1 is a schematic plan view of an insulated gate bipolar transistor (IGBT) according to one or more embodiments of the present disclosure;

FIG. 2 is a cross-sectional view of the IGBT of FIG. 1;

FIGS. 3A-B are reference diagrams useful for describing improved characteristics of an insulated gate bipolar transistor having a second ring region; and

FIGS. 4 to 12 are cross-sectional views illustrating a method of manufacturing an insulated gate bipolar transistor according to one or more embodiments of the present disclosure.

### DESCRIPTION OF THE EMBODIMENTS

Hereinafter, embodiments of the present disclosure will be described in more detail with reference to the accompanying drawings. Embodiments of the present disclosure may be modified in various forms, and the scope of the present disclosure should not be construed as being limited to the following examples, but should be interpreted based on the matters described in the claims. In addition, the present embodiments are provided as a reference for more completely explaining the present disclosure to those with average knowledge of the art.

As used in the present specification, the singular form may include the plural form, unless it clearly points out otherwise in the context. Furthermore, when used herein, “comprise” and/or “comprising” specify the presence or addition of one or more shapes, numbers, steps, operations, members, elements, and/or groups, and do not exclude the presence or addition of one or more other shapes, numbers, steps, operations, members, elements, and/or groups.

Hereinafter, when one component (or layer) is described as being on another component (or layer), it should be noted that the one component may be directly on the other component, or one or more third components or layers may be between the one component and the other component. In addition, when an element is expressed as being directly on or above another element, no other element is between the one element and the other element. Also, being on the “upper”, “lower”, “one side” or “side” of a component means a relative positional relationship.

In the embodiments described below, the first conductivity type may be P-type, and the second conductivity type may be N-type, but is not necessarily limited thereto.

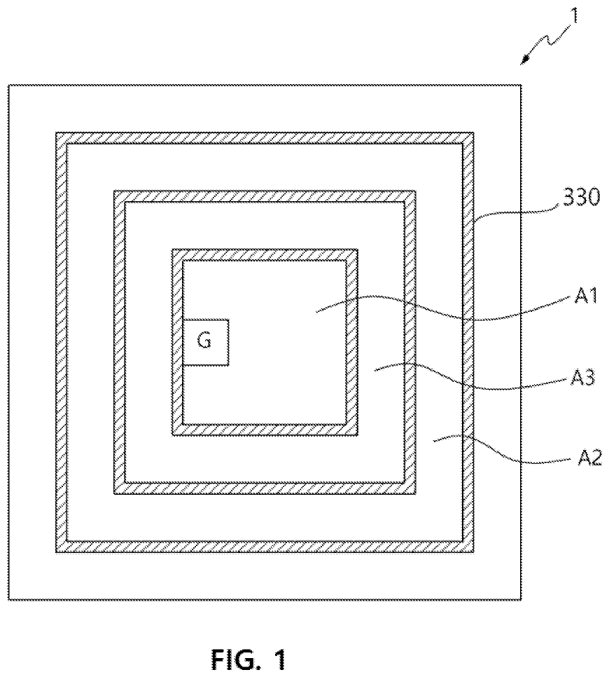

FIG. 1 is a schematic plan view of an insulated gate bipolar transistor according to one or more embodiments of the present disclosure.

Referring to FIG. 1, an insulated gate bipolar transistor 1 according to one or more embodiments of the present disclosure, includes an active region A1 including a gate pad G and a plurality of cells for conducting current; a termination region A2 surrounding the active region A1 and serving as an edge termination region (and, e.g., supporting a high breakdown voltage); and a peripheral region A3, which may include a gate bus line (not shown) connected to the gate pad P and transmitting a gate signal, between the active region A1 and the termination region A2. Hereinafter, a detailed description of the peripheral region A3 is omitted. In addition, although the peripheral region A3 is between the active region A1 and the termination region A2, the peripheral region A3 is omitted in the drawings.

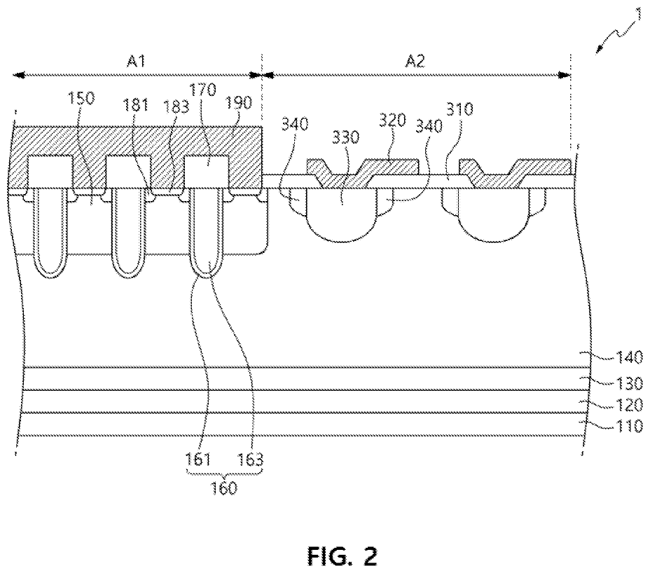

FIG. 2 is a cross-sectional view of the insulated gate bipolar transistor of FIG. 1.

Herein, an insulated gate bipolar transistor 1 according to one or more embodiments of the present disclosure will be described in detail with reference to the accompanying drawings.

Referring to FIGS. 1 and 2, the present disclosure relates to an insulated gate bipolar transistor 1, and more particularly, to an insulated gate bipolar transistor 1 that promotes improved breakdown voltage characteristics and includes a second ring region 340 having the first conductivity type in contact with a first ring region 330 having the first conductivity type in the termination region A2.

First, the structure of the active region A1 will be described in detail below.

On a collector electrode 110 comprising, for example, a metal alloy (e.g., an AlMoNiAu alloy), is a collector layer 120, comprising a high-concentration impurity region having a first conductivity type (e.g., as a conductor or semiconductor layer). A buffer layer 130 is on the collector layer 120 and may comprise a high-concentration impurity region having a second conductivity type. In addition, a drift region 140 comprising an impurity region having the second conductivity type is on the buffer layer 130. For example, the drift region 140 may comprise a low-concentration impurity region having the second conductivity type. As will be described later, the collector layer 120, the buffer layer 130, and the drift region 140 may be in the active region A1, the peripheral region A3, and the termination region A2 (e.g., extend from the active region A1 to the termination region A2).

A body region 150 comprising an impurity region having the first conductivity type is on or in the drift region 140, and a channel region (not identified) is in the body region 150. The channel region is a portion of the body region 150 that is inverted to the second conductivity type when the gate voltage exceeds a turn-on threshold to form a current path.

A trench gate 160 is in the body region 150. It is preferable that such the gate 160 penetrates the body region 150 from the uppermost surface of the body region 150 into the drift region 140 (e.g., so that the bottom of the gate 160 is approximately within the drift region 140). A plurality of the trench gates 160 may be horizontally spaced apart from each other, and body region portions 150 may be between adjacent, spaced apart trench gates 160.

Each trench gate 160 includes a gate insulating layer 161 and a gate electrode 163 on an inner wall of the gate insulating layer 161 (e.g., filling the trench). For example, the gate insulating layer 161 may comprise a silicon oxide layer, and the gate electrode 163 may comprise a polysilicon layer doped with second conductivity type impurities. As described above, a plurality of trench gates 160 are spaced apart from each other by a predetermined distance. The gate electrode 163 may face the body region 150 having the first conductivity type through the gate insulating layer 161, thereby forming a channel in the body region 150 (e.g., when the gate electrode 163 has a voltage thereon within a predetermined range).

The gates 160 may be covered with an interlayer insulating layer 170. The interlayer insulating film 170 may comprise, for example, a doped or undoped silicate glass (e.g., a borophosphosilicate glass [BPSG]), but is not limited thereto. In addition, an emitter electrode 190 is on the surface of the device. An emitter region 181 and a body contact 183, which will be described later, are in the body region 150, at an uppermost surface thereof. The emitter electrode 190 may comprise, for example, a conductive metal film or a doped polysilicon film.

At the surface of the body region 150, emitter regions 181, which comprise high-concentration impurity regions having the second conductivity type, are spaced apart from each other and may have a band shape, for example. One side of the emitter region 181 is in contact with the gate insulating film 161, and an opposite side is in contact with or overlaps with the body contact 183, which comprises a high-concentration impurity region having the first conductivity type (to be described later).

The body contacts 183 contact or partially overlap the emitter regions 181 (between adjacent gates 160) and the body region 150. The impurity concentration of the body contact 183 is higher than that of the body region 150, and since carriers (e.g., electrons or holes) can easily move through the body contact 183, the switching speed may increase.

Looking at the specific operation method of the insulated gate bipolar transistor 1 of the present disclosure, when a positive voltage or voltage differential is applied between the emitter electrode 190 and the collector electrode 110, and a voltage higher than the threshold voltage is applied to the gate electrode 163 (e.g., to turn on the gate 160), the channel region inverts to the second conductivity type. Thereafter, electrons from the emitter electrode 190 move to the collector electrode 110 via the emitter region 181, the channel region, the drift region 140, and the collector layer 120. Accordingly, current flows from the collector electrode 110 to the emitter electrode 190.

When the device 1 is off, a voltage or voltage differential may be applied between the collector electrode 110 and the emitter electrode 190 so that the voltage is distributed in an opposite direction between the body region 150 and the drift region 140. As the voltage between the collector electrode 110 and the emitter electrode 190 gradually increases, the device 1 may eventually enter a breakdown state. In this state, the electric field may be concentrated on, in or at the P-N junction region and a region at or adjacent to the bottom of the trench gate 160.

When the gate is turned off, the electron and hole carriers in the drift region 140 respectively move to the collector electrode 110 and the emitter electrode 190. The holes move to the emitter electrode 190 through the body contact 183.

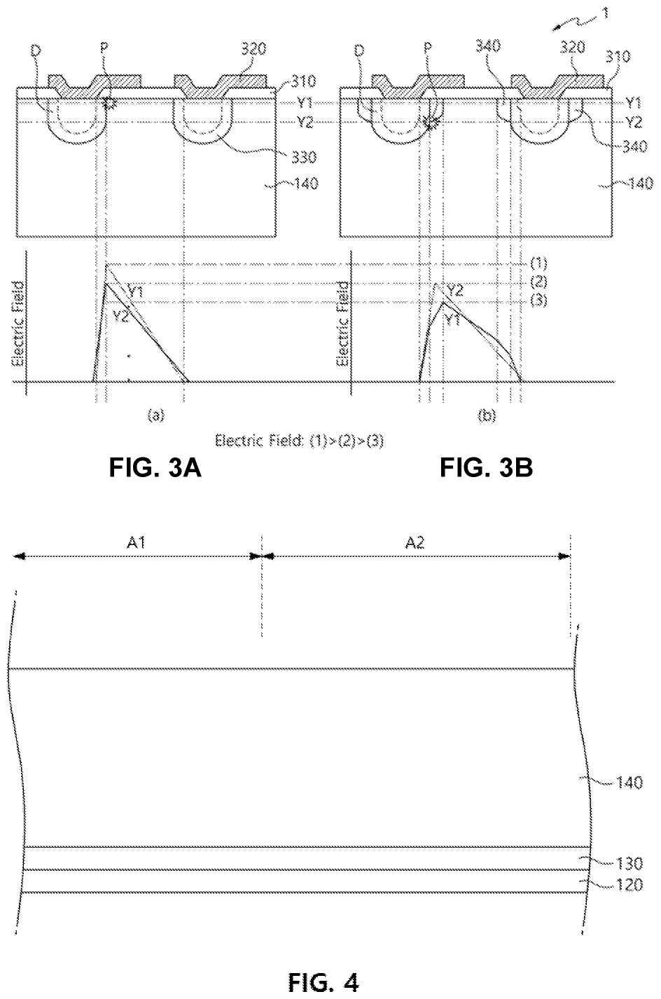

FIGS. 3A-B are reference diagrams for explaining improved characteristics of insulated gate bipolar transistors including a second ring region.

Hereinafter, the structure of the termination region A2 will be described in detail.

Referring to FIGS. 1 to 3, a field oxide 310 may be on the substrate surface in the termination region A2, and a field plate 320 may be on the field oxide 310. The field plate 320 may comprise a doped polysilicon film or a conductive metal film and is not particularly limited thereto. A plurality of the field plates 320 may be in the termination region A2 to mitigate an electric field generated in the active region A1. Also, individual field plates 320 may be connected to the first ring region 330 (which is, in turn, in the drift region 140). That is, each field plate 320 may be connected to the first ring region 330 through a contact hole in the field oxide 310. The first ring region 330 comprises an implant region doped with high-concentration impurities having the first conductivity type, and the termination region A2 may include a plurality of first ring regions 330, spaced apart from each other in the drift region 140. In addition, the first ring region 330 may also be in the peripheral region A3 (see FIG. 1).

The first ring region 330 may extend in the termination region A2 and/or the drift region 140 through P-N bonding or along a P-N interface, thereby providing high breakdown voltage characteristics. The first ring region 330 comprises a high-concentration impurity doped region having the first conductivity type and may have a high electric field peak value in the P-N junction region. In particular, a breakdown occurs in the IGBT when the critical electric field value is reached. Referring to FIG. 3A, a breakdown point P occurs at or near the substrate surface during a high electric field peak at a height or depth Y1 in the drift region 140 at or near the interface with the first ring region 330, resulting in the IGBT being vulnerable to high-temperature reverse bias (HTRB) characteristics.

In order to prevent this problem, referring to FIG. 3B, the insulated gate bipolar transistor 1, according to one or more embodiments of the present disclosure, includes the second ring region 340 having the first conductivity type in the substrate/drift region 140 and in contact with the first ring region 330 in the termination region A2. The second ring region 340 comprises an impurity doped region having the first conductivity type, and has a lower dopant concentration than that of the first ring region 330. As a result of the P-N interface between the first ring region 330 and the drift region 140, the depletion region D extends significantly toward the ring regions 330 and 340, thereby lowering the electric field peak value at the heights or depths Y1 and Y2, thereby ensuring stable breakdown voltage characteristics. In addition, the breakdown point P relocates from the substrate surface to the bottom of the second ring region 340 (e.g., at the interface with the first ring region 330), thereby ensuring relatively stable high-temperature reverse bias characteristics.

The second ring region 340 may contact a side of the first ring region 330 relatively distant from the active region A1 and/or a side of the first ring region 330 nearer or adjacent to the active region A1, but is not limited thereto. In addition, it is preferable that the second ring region 340 has a depth about half of that of the first ring region 330, measured from an uppermost surface of the drift region 140.

FIGS. 4 to 12 are cross-sectional views illustrating a method of manufacturing an insulated gate bipolar transistor, according to embodiments of the present disclosure.

Hereinafter, a method of manufacturing an insulated gate bipolar transistor according to embodiments of the present disclosure will be described in detail with reference to the accompanying drawings. Meanwhile, when an embodiment can be implemented differently, each process or step may occur in a different order from the described order. For example, two processes or steps described may be performed substantially concurrently or in a reverse order.

Referring to FIG. 4, for example, a buffer layer 130 is formed on the collector layer 120. For example, the buffer layer 130 may comprise silicon having a high-concentration of second conductivity type impurities therein. The buffer layer 130 may be formed by, for example, epitaxial growth. The impurities may be added during epitaxial growth or by ion implantation, after epitaxial growth.

Then, the drift region 140 is formed on the upper side of the buffer layer 130. The drift region 140 may comprise silicon having a low concentration of second conductivity type impurities therein. The drift region 140 may be formed by, for example, epitaxial growth, similarly to the buffer layer 130. However, the drift region 140 may comprise a plurality of cycles of epitaxial growth, optionally followed by ion implantation when the epitaxial growth does not include the impurities.

Thereafter, the first ring region 330 and the second ring region 340 are formed in the termination region A2. One or more of each of the ring regions 330 and 340 are formed in the termination region A2, and it is preferable that a plurality of the first ring regions 330 and a plurality of the second ring regions 340 are formed in the termination region A2. This will be explained in detail.

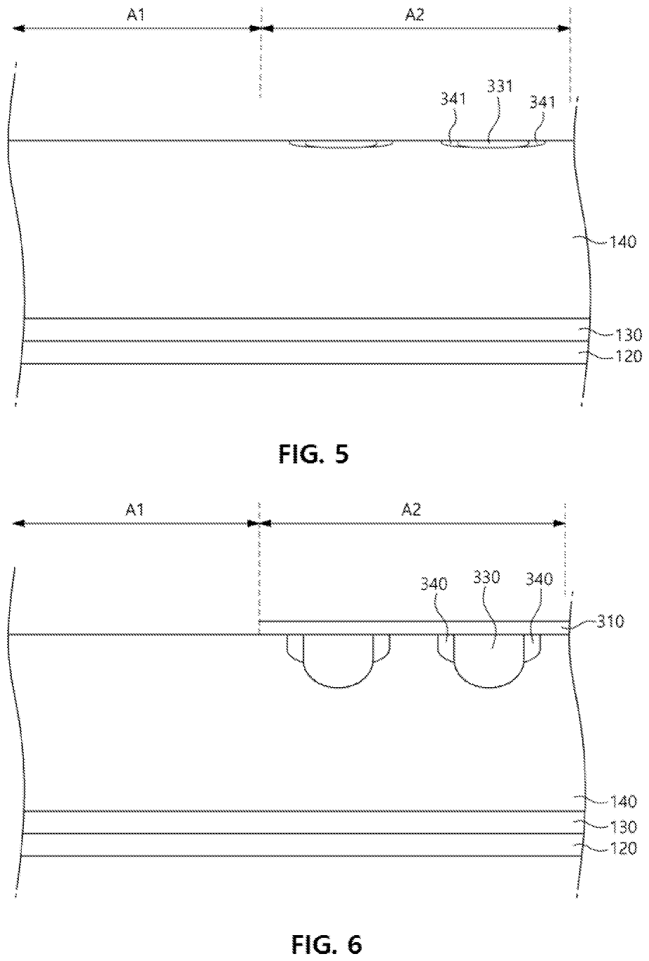

Referring to FIG. 5, a first implant layer 331 is formed by implanting a high concentration of impurities using a photoresist pattern (not shown) as a mask into the drift region 140. In addition, a second implant layer 341 is formed by implanting a low concentration of impurities into the drift region 140, in an area overlapping one or both of horizontal/peripheral edges of the first implant layer 331 as shown in FIG. 5. Both the first implant layer 331 and the second implant layer 341 include impurities having the first conductivity type, and the first implant layer 331 is a relatively high-concentration doped region.

Then, referring to FIG. 6, the first ring region 330 and the second ring region 340 are formed by thermally diffusing the implant layers 331 and 333 through a drive-in (e.g., a dopant activation) process. As described above, the second ring region 340 increases the width of the ring region in the termination region A2 to enable the IGBT to withstand relatively high voltages, thereby increasing and/or stabilizing the breakdown voltage of the IGBT.

Thereafter, a field oxide 310 is formed on the drift region 140 in the termination region A2. The field oxide 310 may comprise, for example, undoped silicon dioxide, and be formed by local oxidation of silicon (LOCOS), but is not limited thereto.

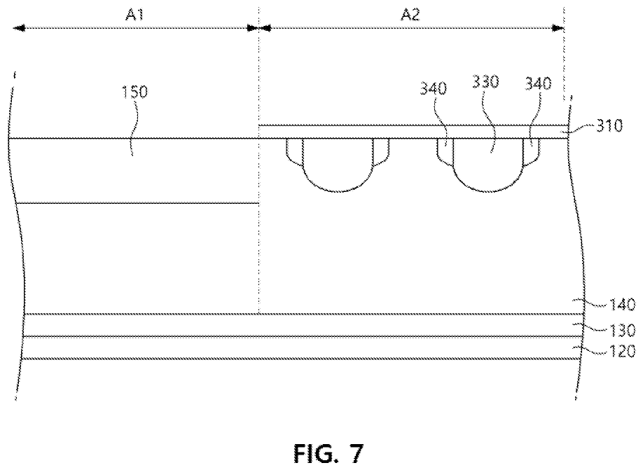

Referring to FIG. 7, a body region 150 is formed on or in the drift region 140 in the active region A1. For example, the body region 150 may be formed by implanting impurities having the first conductivity type and annealing (e.g., a drive-in and/or dopant activation process).

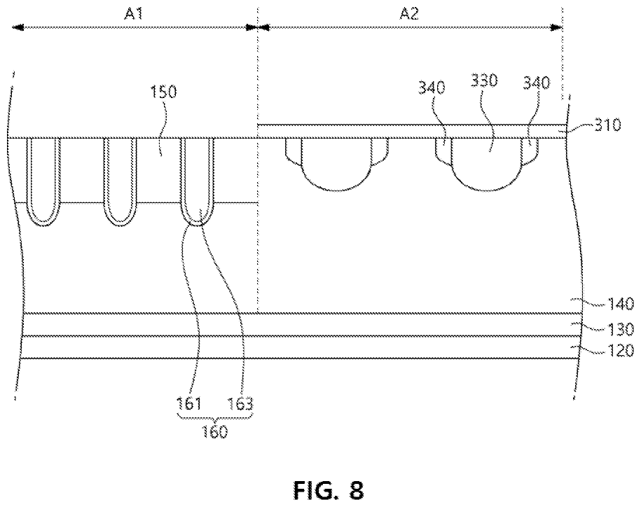

Then, referring to FIG. 8, a gate 160 is formed. For example, a patterned oxide film or a patterned bilayer of silicon nitride on silicon dioxide (not shown) may be formed as a mask or a shielding film on the surface of the body region 150. Thereafter, areas of the body region 150 exposed through the openings in the mask or shielding film may be etched to form a plurality of trenches through the body region 150 (e.g., extending from the uppermost surface of the body region 150, through the body region 150, to the drift region 140). As a result, the body region 150 may have a plurality of portions that are physically separated or spaced apart from each other. Then, the patterned oxide film or patterned bilayer may be removed.

Subsequently, an oxide film (e.g., silicon dioxide) is conventionally formed on the inner wall of the trenches to form the gate insulating film 161. In one embodiment, in the presence of the patterned oxide film or patterned bilayer, the body region 150 exposed in the trenches may be thermally oxidized to form the gate insulating film 161. Alternatively, after removal of the patterned oxide film or patterned bilayer, a silicon dioxide layer may be conformally deposited into the trenches and onto the uppermost surface of the body region 150. Then, polysilicon doped with second conductivity type impurities is deposited on the silicon dioxide layer including the gate insulating film 161 to fill the trenches. The polysilicon doped with second conductivity type impurities and the silicon dioxide layer on or above the uppermost surface of the body region 150 are removed conventionally (e.g., by etchback or wet etching), in which case the field oxide 310 may be conventionally protected (e.g., with a photoresist).

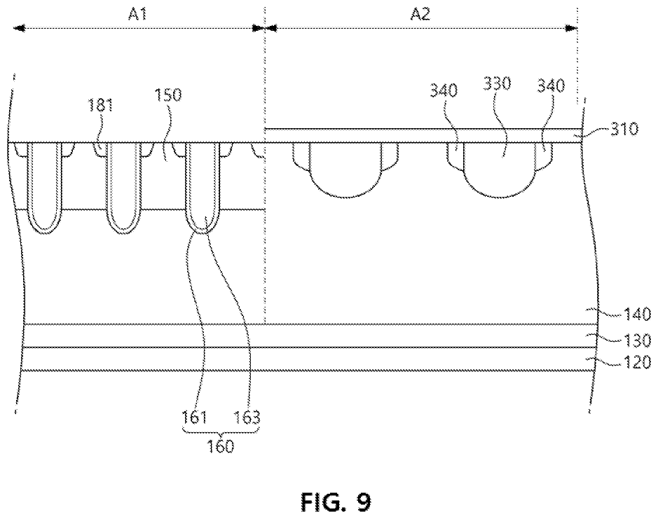

After that, referring to FIG. 9, emitter regions 181 are formed in the body region 150, at the uppermost surface thereof. A photoresist pattern (not shown) having openings corresponding to the emitter regions 181 is formed on the body region 150, and a high concentration of impurities having a second conductivity type are implanted into the body region 150 using the photoresist pattern (not shown) as a mask. The photoresist pattern is then removed. A band-shaped region, including the emitter region 181, may be formed in the body region 150 through the implanted impurities.

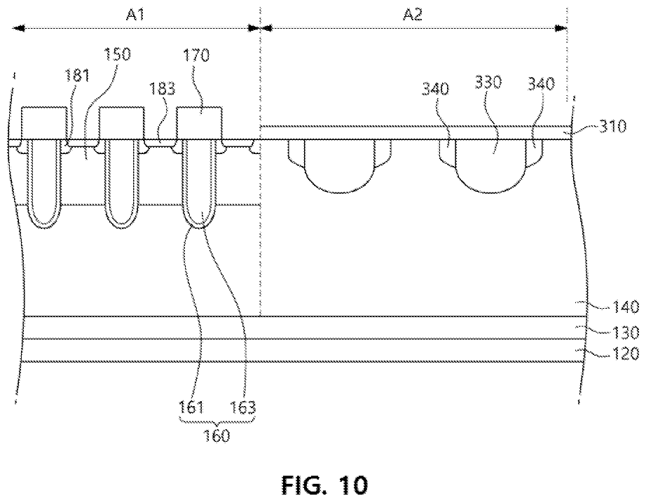

Referring to FIG. 10, a body contact 183 is formed in a subsequent process. Illustratively, using a photoresist pattern (not shown) as a mask, a high concentration of impurities having the first conductivity type are ion-implanted into exposed areas of the body region 150, and the photoresist pattern is removed. Then, a heat treatment (e.g., a drive-in and/or dopant activation) process is performed on the implanted impurities to form the body contact 183 and the emitter regions 181.

After that, an interlayer insulating film 170 is formed on the body region 150 and the gates 160. An insulating film (e.g., a multi-layer insulating film) is deposited on the body region 150 and the gates 160, then the insulating film is etched using a photoresist pattern (not shown) as a mask. Thus, the interlayer insulating film 170 covering at least the gates 160 is formed. Then, the photoresist pattern (not shown) is removed.

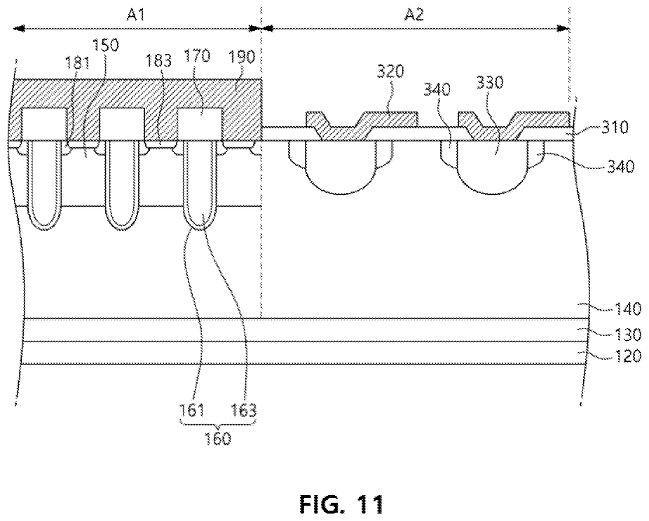

Referring to FIG. 11, in the active region A1, an emitter electrode 190 may be formed by depositing a conductive layer on the exposed body contacts 183 and the interlayer insulating film 170. The emitter regions 181 are preferably covered by the interlayer insulating film 170, but the invention is not limited thereto.

At this time, the field plate(s) 320 may also be formed in the termination region A2. Contact holes (not shown) may be formed by etching the field oxide 310 over the first ring region(s) 330 in the termination region A2 (optionally at the same time that the insulating film forming the interlayer insulating film 170 is etched), and a field plate film (not shown) is blanket-deposited on the resulting structure. The material of the emitter electrode 190 and the field plate film may be the same, but the invention is not limited thereto. Thereafter, the field plate film may be etched to form the field plate(s) 320 on the individual first ring regions 330.

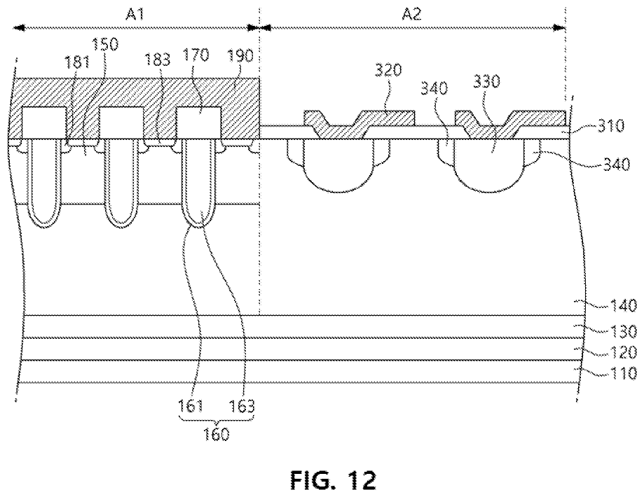

Referring to FIG. 12, the collector electrode 110 is formed on the surface of the substrate 120 opposite from the buffer layer 130. As described above, the collector electrode 110 may comprise an alloy of aluminum, molybdenum, nickel, and/or gold (e.g., an AlMoNiAu alloy).

The above detailed description is illustrative of the present disclosure. In addition, the above description shows and describes various embodiments of the present disclosure, and the present disclosure may be used in various environments such that various embodiments are diversely combined or modified. That is, various changes or modifications to the embodiments are possible without departing from the scope of the concept of the disclosure disclosed herein, the scope equivalent to the written disclosure, and/or the scope of skill or knowledge in the relevant art. The embodiments are provided to describe various states for implementing the technical idea of the present disclosure, and various changes required in the specific applications and uses of the present disclosure are possible. Therefore, the detailed description of the present disclosure is not intended to limit the present disclosure to the disclosed embodiments.

What is claimed is:

1. An insulated gate bipolar transistor comprising:
a collector electrode;
a collector layer on the collector electrode;
a drift region on or over the collector layer;
a field oxide on the drift region;
a first ring region in the drift region;
a second ring region in contact with the first ring region in the drift region; and
a field plate connected to the first ring region.

2. The insulated gate bipolar transistor of claim 1, wherein the first ring region comprises a high-concentration impurity doped region having a first conductivity type, and the second ring region comprises a low-concentration impurity doped region having a first conductivity type.

3. The insulated gate bipolar transistor of claim 2, wherein the first ring region and the second ring region are at a surface of the drift region, and the second ring region has a depth of about half of a depth of the first ring region.

4. The insulated gate bipolar transistor of claim 2, wherein the second ring region is in contact with a side of the first ring region relatively distant from an active region of the insulated gate bipolar transistor.

5. The insulated gate bipolar transistor of claim 2, wherein the second ring region is in contact with first and second sides of the first ring region, the second side of the first ring region being closer or nearer to an active region of the insulated gate bipolar transistor, and the first side of the first ring region being more distant from the active region than the second side.

6. The insulated gate bipolar transistor of claim 2, wherein the field plate is connected to the first ring region through a contact hole in the field oxide.

7. An insulated gate bipolar transistor comprising:
a collector electrode;
a collector layer having a first conductivity type on the collector electrode;
a drift region having a second conductivity type on the collector layer;
a body region having a first conductivity type in the drift region, in an active region of the insulated gate bipolar transistor;
a plurality of trench gates in the body region;
an interlayer insulating film on at least the plurality of trench gates;
an emitter region having a second conductivity type on or in the body region;
an emitter electrode on the interlayer insulating film;
a field oxide on the drift region, in a termination region of the insulated gate bipolar transistor;
a first ring region comprising a high-concentration impurity doped region having a first conductivity type in the drift region, in the termination region;
a second ring region comprising a low-concentration impurity doped region having a first conductivity type and in contact with the first ring region in the drift region; and
a field plate connected to the first ring region, through and/or on the field oxide.

8. The insulated gate bipolar transistor of claim 7, further comprising a body contact having a first conductivity type in contact with the emitter region in the body region.

9. The insulated gate bipolar transistor of claim 7, further comprising a buffer layer having a second conductivity type on the collector layer.

10. The insulated gate bipolar transistor of claim 7, wherein each of the plurality of trench gates comprises:
a gate insulating film on an inner wall of a trench; and
a gate electrode on the gate insulating film and filling the trench.

11. The insulated gate bipolar transistor of claim 7, comprising a plurality of the first ring regions, spaced apart from each other in the drift region, and connected to a corresponding one of a plurality of the field plates, and a plurality of the second ring regions spaced apart from each other and in contact with corresponding ones of the first ring regions in the drift region.

12. The insulated gate bipolar transistor of claim 11, wherein each of the plurality of second ring regions is electrically connected to at least one side of the corresponding first ring region.

13. The insulated gate bipolar transistor of claim 11, wherein each of the plurality of second ring regions has a smaller height or depth than that of the corresponding first ring region.

14. A method of manufacturing an insulated gate bipolar transistor, the method comprising:
forming a collector layer on a substrate;
forming a drift region on or over the collector layer;
forming a body region on or in the drift region in an active region of the insulated gate bipolar transistor;
forming a plurality of trench gates in the body region;
forming an emitter region on or in the body region, spaced from each other;
forming an interlayer insulating film on or over the plurality of trench gates;
forming a plurality of first ring regions on or in the drift region in a termination region of the insulated gate bipolar transistor; and
forming a plurality of second ring regions on or in the drift region and in contact with individual first ring regions.

15. The method of claim 14, wherein forming the first ring region and the second ring region comprises:
forming a plurality of first implant layers, each comprising a high-concentration doped region having a first conductivity type, in the drift region in the termination region;
forming a plurality of second implant layers, each comprising a low-concentration doped region having a second conductivity type, in contact with corresponding ones of the first implant layers; and
diffusing the first implant layer and the second implant layer.

16. The method of claim 15, wherein the method further comprises:
forming a field oxide on the drift region in the termination region; and
forming a plurality of field plates electrically connected to corresponding ones of the first ring regions, through and/or on the field oxide.

17. The method of claim 16, wherein the method further comprises forming an emitter electrode in an active region of the insulated gate bipolar transistor on the interlayer insulating layer and the body region, substantially simultaneously with the plurality of field plates.

18. The method of claim 15, wherein each of the plurality of second ring regions is connected to at least one side of a corresponding one of the plurality of first ring regions.
